(19) United States
(12) Patent Application Publication
(10) Pub. No.: US 2024/0425360 A1
(43) Pub. Date: Dec. 26, 2024

(54) MEMS RESONATOR AND METHOD FOR PRODUCING THE SAME

(71) Applicant: ROHM CO., LTD., Kyoto (JP)

(72) Inventors: Toma FUJITA, Kyoto-shi (JP); Martin HELLER, Kyoto-shi (JP); Daisuke KAMINISHI, Kyoto-shi (JP)

(73) Assignee: ROHM CO., LTD., Kyoto (JP)

(21) Appl. No.: 18/753,348

(22) Filed: Jun. 25, 2024

(30) Foreign Application Priority Data
Jun. 26, 2023 (JP) 2023-104422

(51) Int. Cl. B81B 3/00; B81C 1/00

(52) U.S. Cl. CPC B81B 3/0086; B81C 1/00698; B81B 2201/0271; B81B 2203/0307; B81B 2203/0315; B81B 2203/04; B81B 2207/11; B81C 2201/0105; B81C 2201/013; B81C 2201/0177; B81C 2203/0172

(57) ABSTRACT

Provided is a MEMS resonator which is inexpensive in manufacturing cost and can secure long-term stability of vibration. A MEMS resonator includes: a substrate; a cavity provided in the substrate; a MEMS structure held within the cavity, the MEMS structure including: an anchor having a first end and a second end, the first end being connected to the substrate; a vibrator connected to the second end of the anchor and held in a hollow; and an electrode disposed around the vibrator, the vibrator and the electrode forming a capacitive vibrator; and a cap layer which is formed over the substrate and seals the MEMS structure therein, in which the anchor includes an isolation joint having an insulation property disposed to electrically insulate the first end from the second end.

### BACKGROUND

### Technical Field

The present invention relates to a MEMS resonator and a method for producing the same, and more particularly to a MEMS resonator using an isolation joint and a method for producing the same.

### Background Art

In MEMS resonators, it is important to use materials with stable material properties (for example, Young's modulus, rigidity modulus, Poisson's ratio, and the like), and, for example, monocrystalline silicon is used. In this case, the silicon substrate is etched to produce an electrode of a MEMS structure, but the electrode and the silicon substrate need to be electrically insulated. Therefore, a silicon on insulator (SOI) substrate is usually used, and an electrode is produced in a silicon layer on the insulating layer.

In the MEMS resonator, after the MEMS structure is produced in the silicon layer, a silicon substrate is separately prepared, and the silicon substrate is bonded on the SOI substrate by glass frit bonding, thereby sealing the MEMS structure between the two substrates. For this glass frit bonding, a relatively low temperature such as 450° C. is used.

### BRIEF DESCRIPTION OF DRAWINGS

FIG. 1 is a plan view schematically illustrating a MEMS resonator according to an embodiment of the present invention;

FIG. 2 is a sectional view of the MEMS resonator taken along line A-A in FIG. 1;

FIG. 3 is a sectional view of a producing step of the MEMS resonator according to the embodiment of the present invention;

FIG. 4 is a sectional view of a producing step of the MEMS resonator according to the embodiment of the present invention;

FIG. 5 is a sectional view of a producing step of the MEMS resonator according to the embodiment of the present invention;

FIG. 6 is a sectional view of a producing step of the MEMS resonator according to the embodiment of the present invention;

FIG. 7 is a sectional view of a producing step of the MEMS resonator according to the embodiment of the present invention;

FIG. 8 is a sectional view of a producing step of the MEMS resonator according to the embodiment of the present invention;

FIG. 9 is a sectional view of a producing step of the MEMS resonator according to the embodiment of the present invention;

FIG. 10 is a sectional view of a producing step of the MEMS resonator according to the embodiment of the present invention;

FIG. 11 is a sectional view of a producing step of the MEMS resonator according to the embodiment of the present invention;

FIG. 12 is a sectional view of a producing step of the MEMS resonator according to the embodiment of the present invention;

FIG. 13 is a sectional view of a producing step of the MEMS resonator according to the embodiment of the present invention;

FIG. 14 is a sectional view of a producing step of the MEMS resonator according to the embodiment of the present invention;

FIG. 15 is a sectional view of a producing step of the MEMS resonator according to the embodiment of the present invention;

FIG. 16 is a sectional view of a producing step of the MEMS resonator according to the embodiment of the present invention;

FIG. 17 is a sectional view of a producing step of the MEMS resonator according to the embodiment of the present invention;

FIG. 18 is a sectional view of a producing step of the MEMS resonator according to the embodiment of the present invention;

FIG. 19 is a sectional view of a producing step of the MEMS resonator according to the embodiment of the present invention;

FIG. 20 is a sectional view of a producing step of the MEMS resonator according to the embodiment of the present invention;

FIG. 21 is a sectional view of a producing step of the MEMS resonator according to the embodiment of the present invention; and

FIG. 22 is a sectional view of a producing step of the MEMS resonator according to the embodiment of the present invention.

### DETAILED DESCRIPTION

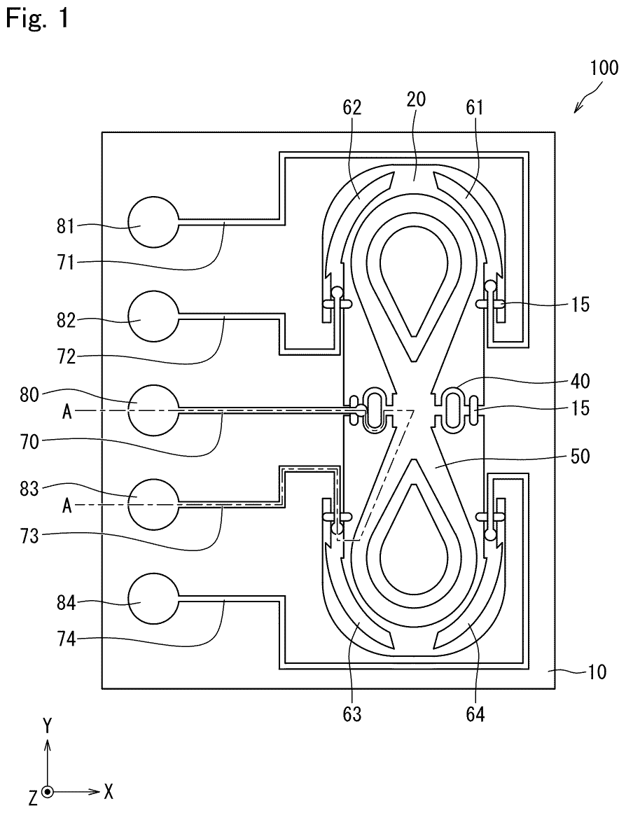

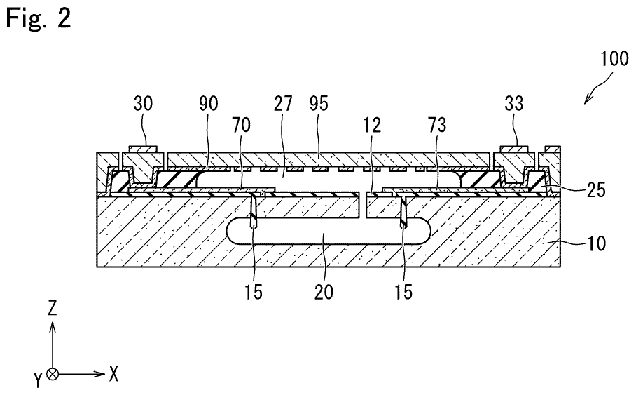

FIG. 1 is a plan view schematically illustrating a MEMS resonator according to an embodiment of the present invention, generally indicated by 100. Here, for ease of explanation, a cap layer, an electrode pad, and the like are omitted. Further, FIG. 2 is a sectional view of the MEMS resonator taken along line A-A in FIG. 1. Since FIG. 1 is a schematic view, dimensions and the like are not necessarily consistent with those in FIG. 2.

The MEMS resonator 100 includes a substrate 10 made of, for example, single crystal silicon. A lower cavity 20 is provided in a part of the substrate 10. A pair of anchors 40 extending in the X-axis direction and held in a hollow is provided above the lower cavity 20. The anchors 40 are MEMS structures produced by etching the substrate 10 and are connected to opposing side surfaces of the cavity 20, respectively. An isolation joint (IJ) 15 made of, for example, silicon oxide is provided in the middle of the anchor 40. Further, in the anchor 40 of FIG. 1, a part is formed into an elliptical structure so as to be easily deformed, but the elliptical structure may not be provided.

The MEMS resonator 100 further includes a vibrator 50 held over the lower cavity 20 by the pair of anchors 40. The vibrator 50 is also a MEMS structure produced by etching the substrate 10, and has a mirror-symmetrical (or point-symmetrical) structure with respect to the XY plane including the X axis in which the anchors 40 extend. Although the shape is the shape of 8 in FIG. 1, other mirror-symmetrical shapes may be used.

Four counter electrodes 61 to 64 are provided at four corners around the vibrator 50. The counter electrodes 61 to 64 are also formed of a MEMS structure produced by etching the substrate 10, and is electrically insulated from the substrate 10 with an isolation joint (IJ) provided in the middle.

Wiring layers 70 to 74 made of, for example, polycrystalline silicon and electrodes 80 to 84 are provided on the substrate 10. The wiring layer 70 is electrically connected to the anchor 40 and the vibrator 50 from the electrode 80 through above the IJ. The wiring layers 72 to 74 electrically connect the electrodes 81 to 84 and the counter electrodes 61 to 64. The wiring layers 70 to 74 are connected to the respective counter electrodes 61 to 64 from the electrodes 80 to 84 through above the IJs.

As can be seen from FIG. 2, an oxide film 12 made of silicon oxide is provided on the substrate 10 to electrically insulate the wiring layers 72 to 74 from the substrate 10. In addition, the top of the substrate 10 is covered with a cap layer 95 to seal the vibrator 50 inside.

Next, an operation of the MEMS resonator 100 will be described. In the MEMS resonator 100, the four counter electrodes 61 to 64 and the vibrator 50 are disposed to face each other to form a capacitive vibrator. The vibrator 50 is supported in a hollow by the pair of anchors 40 in cavities 20 and 27, and has a structure in which both ends (upper and lower ends in FIG. 1) move in the Z-axis direction around the anchors 40 like a seesaw.

The capacitive vibrator is driven by an electrostatic attractive force generated by a potential applied between the counter electrodes 61 to 64 and the vibrator 50. Specifically, the electrode 80 connected to the vibrator 50 is set to a constant voltage (reference voltage), and a positive voltage is alternately applied to the electrodes 81 and 84. As a result, electrostatic attractive forces alternately act between the counter electrode 61 and the vibrator 50 and between the counter electrode 64 and the vibrator 50, and the vibrator 50 vibrates like a seesaw around the anchors 40.

Here, in a case where an electrostatic attractive force is generated between the counter electrodes 61 and 64 and the vibrator 50, since the electrostatic attractive force is asymmetric with respect to the vibration center (the center of the anchors 40), a desired vibration mode may not be obtained, or an unnecessary vibration mode may be generated. Therefore, when a positive voltage is applied to the counter electrode 61 or the counter electrode 64, a negative voltage is applied to the counter electrodes 61 and 64 disposed symmetrically with respect to the counter electrodes 62 and 63, and the vibrator 50 is also pulled in a direction symmetric with respect to the center of vibration. As a result, asymmetric vibration is prevented, and desired vibration can be obtained. Specifically, a constant voltage of 2.5 V is applied to the electrode 80, and voltages of 5 V and 0 V are alternately applied to the electrodes 81 and 84 and the electrodes 82 and 83.

As described above, by alternately applying voltages having the same magnitude and different signs with respect to the electrode 80 to the electrodes 81 and 84 and the electrodes 82 and 83, the MEMS resonator 100 can be used for an oscillation circuit or a filter as a resonator of a desired frequency. In addition, after the vibration, a voltage between the electrodes is measured to measure a change in resonant frequency, so that the MEMS resonator 100 can also be used as a temperature sensor or the like.

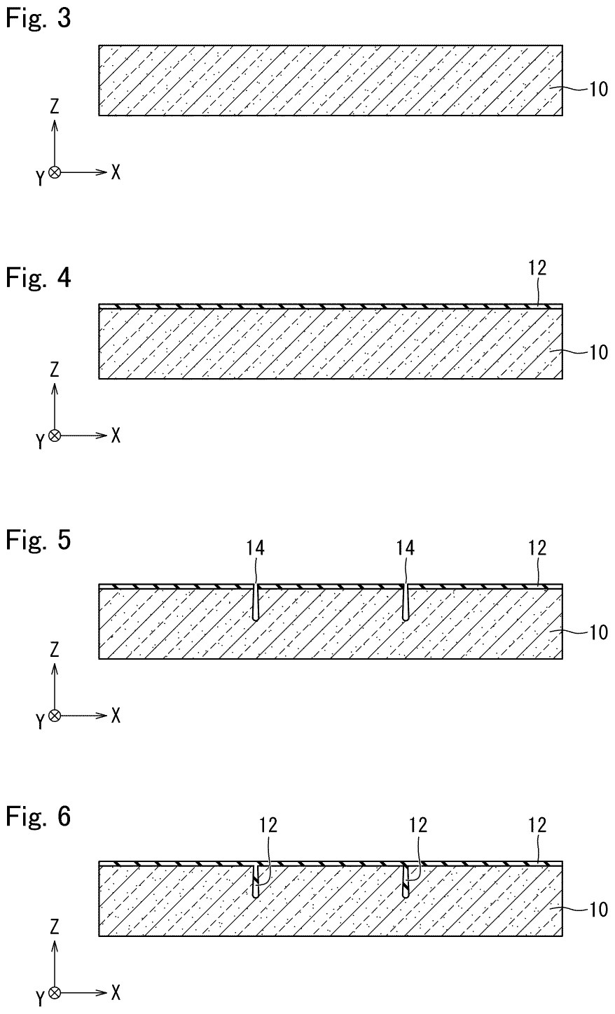

Next, a method for producing the MEMS resonator 100 will be described with reference to FIGS. 3 to 22. The method includes the following steps 1 to 21. In FIGS. 3 to 22, the same reference numerals as those in FIGS. 1 and 2 denote the same or corresponding parts.

Step 1: As illustrated in FIG. 3, the substrate 10 made of, for example, single crystal silicon is prepared.

Step 2: As illustrated in FIG. 4, the oxide film 12 made of, for example, silicon oxide is formed by thermal oxidation.

Step 3: As shown in FIG. 5, after the oxide film 12 is patterned using a resist mask (not shown), trenches 14 are formed in the substrate 10 using the oxide film 12 as a hard mask. The depth of the trench 14 is, for example, 30 μm.

Step 4: As illustrated in FIG. 6, the inner walls of the trenches 14 are thermally oxidized, and the insides of the trenches 14 are filled with the oxide film 12.

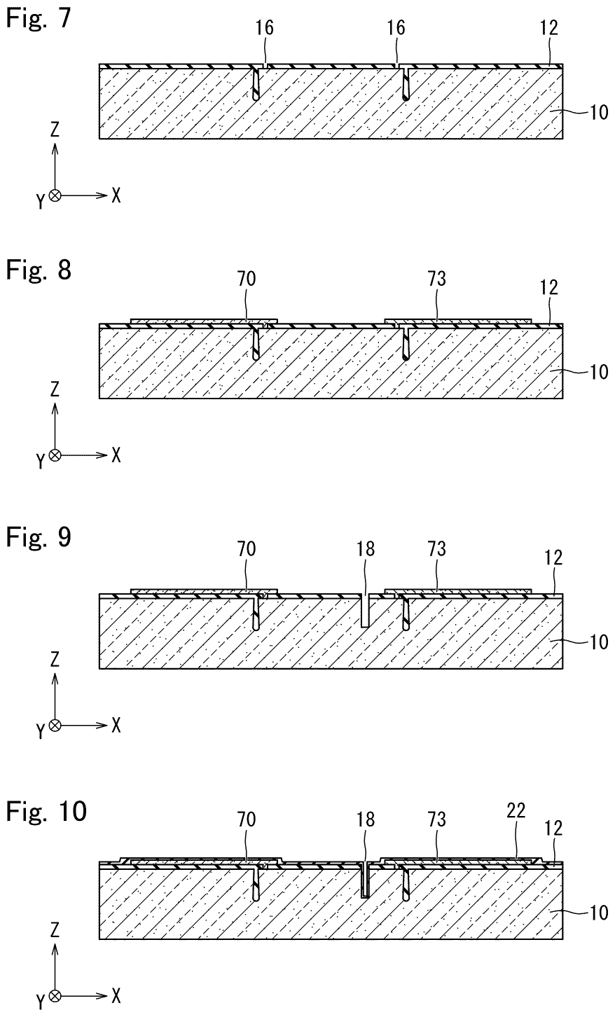

Step 5: As illustrated in FIG. 7, the oxide film 12 on the surface of the substrate 10 is etched using a resist mask (not illustrated) to form the opening 16. The surface of the substrate 10 is exposed at the bottom of the opening 16.

Step 6: As illustrated in FIG. 8, a polycrystalline silicon film having a film thickness of, for example, 0.5 μm is formed on the oxide film 15 by thermal CVD, and subsequently, etching is performed using a resist mask (not illustrated) to form the wiring layers 70 and 73. The polycrystalline silicon is doped with impurities to be conductive. The wiring layers 70 and 73 are connected to the substrate 10 in the opening 16 to form a contact.

Step 7: As illustrated in FIG. 9, the oxide film 12 and the substrate 10 are etched by DRIE using a resist mask (not illustrated) to form an opening 18 around a region to be the MEMS structure (structure etch). The opening 18 has a depth of, for example, 28 μm and a width of, for example, 1 to 3 μm.

Step 8: As illustrated in FIG. 10, an oxide film 22 made of, for example, silicon oxide is formed on the entire surface by plasma CVD. In step 8, the oxide film 22 is also formed on the side surface and the bottom surface of the opening 18.

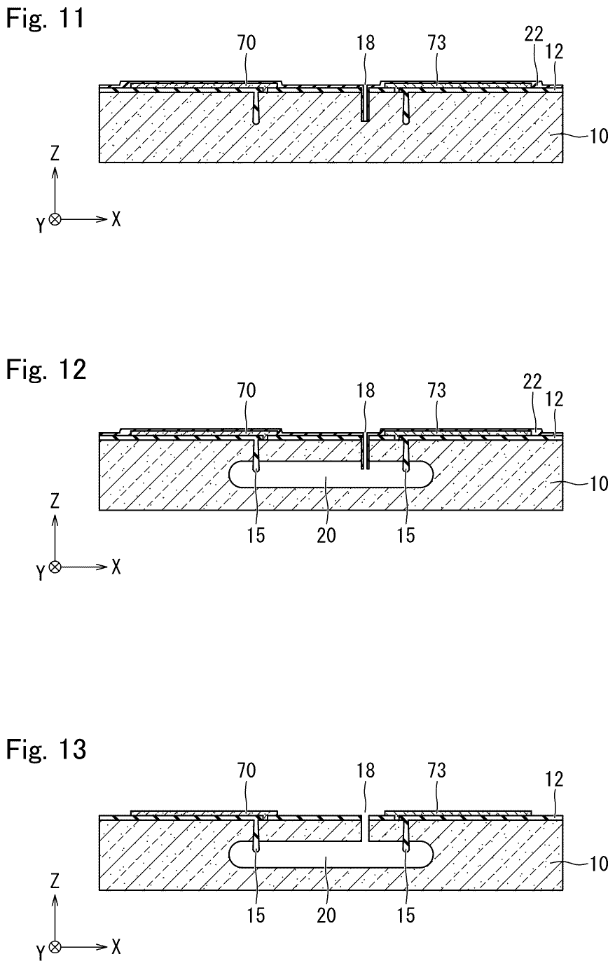

Step 9: As illustrated in FIG. 11, the oxide film 22 on the bottom surface of the opening 18 is removed using, for example, RIE to expose the surface of the substrate 10. In this case, the side surface of the opening 18 remains covered with the oxide film 22.

Step 10: As illustrated in FIG. 12, the substrate 10 is etched through the opening 18 using the SF₆ gas to form the lower cavity 20. The depth of the lower cavity 20 is, for example, 15 μm. In this step, the side walls of the opening 18 are not etched because they are covered by the oxide film 22, and a MEMS structure is formed which is held in a hollow on the lower cavity 20 (structure release). Further, the oxide film 12 buried in the trench 14 has a lower end exposed and becomes an isolation joint (IJ) 15.

Step 11: As shown in FIG. 13, for example, the oxide film 22 may be removed using vapor of hydrofluoric acid. Prior to the next step 12, an ALD film such as Al₂O₃ may be deposited to protect the isolation joint (IJ) 15 from hydrofluoric acid.

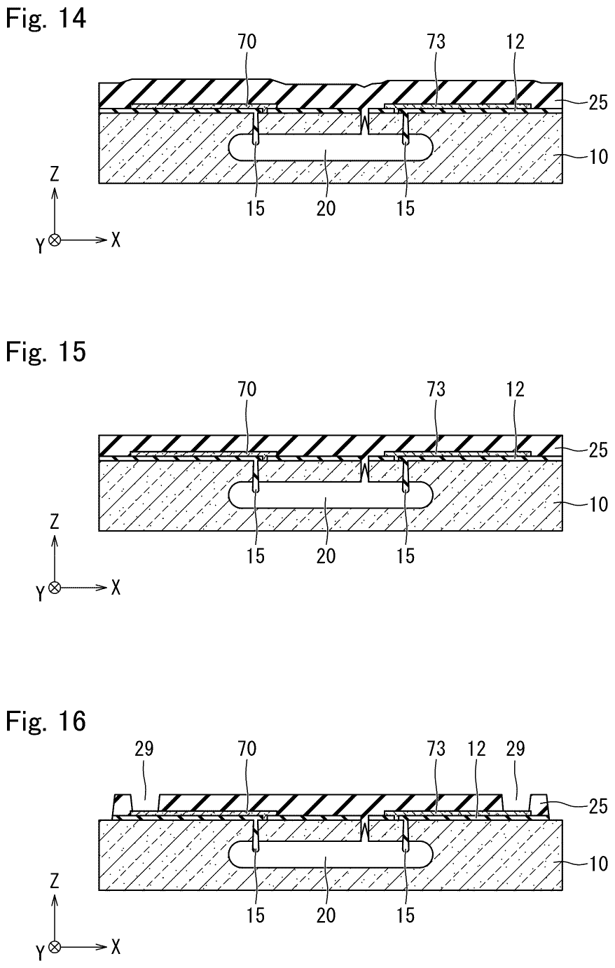

Step 12: As illustrated in FIG. 14, a sacrificial oxide film 25 made of silicon oxide is formed on the entire surface by plasma CVD. The film thickness of the sacrificial oxide film 25 is, for example, 3 to 5 μm.

Step 13: As illustrated in FIG. 15, etch-back using RIE, CMP, or the like is performed to planarize the surface of the sacrificial oxide film 25.

Step 14: As illustrated in FIG. 16, the sacrificial oxide film 25 (the sacrificial oxide film 25 and the ALD film in a case where the ALD film is deposited prior to the step 12) is etched using a resist mask (not illustrated) to form an opening 29. A part of each of the wiring layers 70 and 73 is exposed at the bottom of the opening 29, and this exposed portion corresponds to each of the electrodes 80 and 83 of FIG. 1.

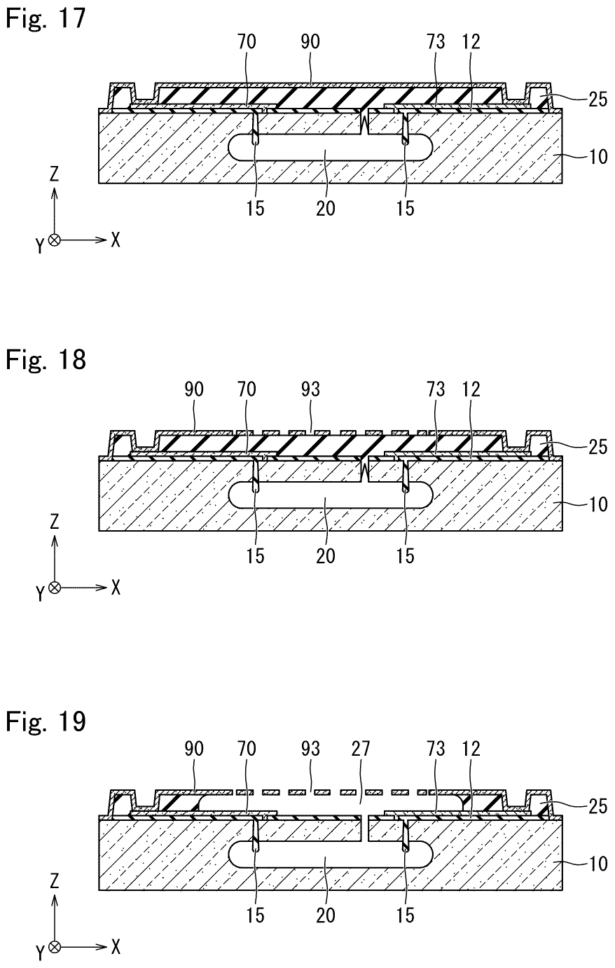

Step 15: As illustrated in FIG. 17, a polycrystalline silicon film 90 having a film thickness of, for example, 1 μm is formed on the entire surface by thermal CVD.

Step 16: As illustrated in FIG. 18, a plurality of release openings 93 are formed in the polycrystalline silicon film 90 using a resist mask (not illustrated). The diameter of the release opening 93 is, for example, 0.1 μm.

Step 17: As illustrated in FIG. 19, the sacrificial oxide film 25 is etched using hydrofluoric acid vapor, and the sacrificial oxide film 25 above the lower cavity 20 is partially removed to form the upper cavity 27. As a result, the MEMS structures such as the anchor 40, the vibrator 50, and the counter electrodes 61 to 64 are held in a hollow between the lower cavity 20 and the upper cavity 27.

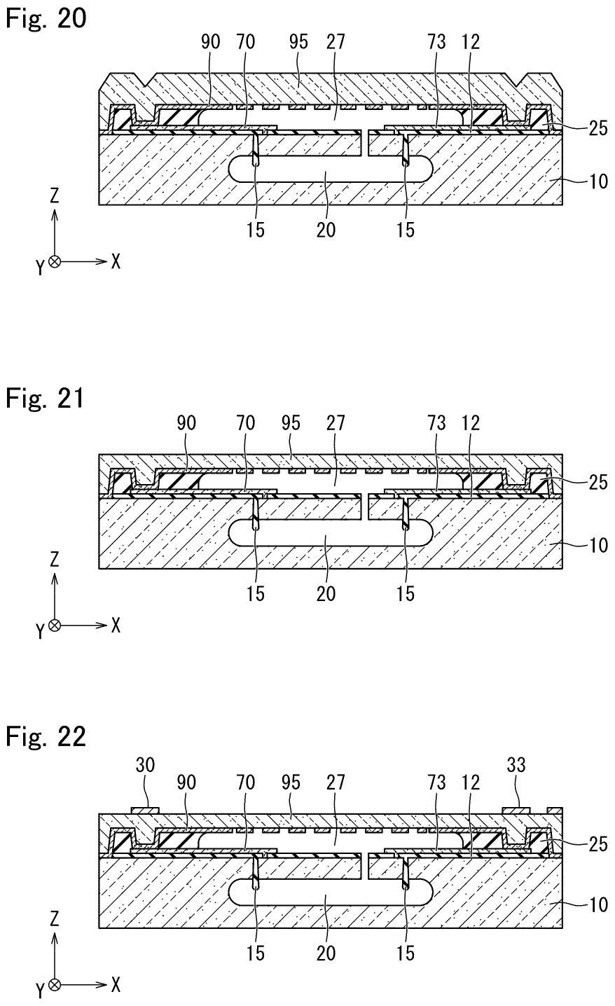

Step 18: As illustrated in FIG. 20, the cap layer 95 made of polycrystalline silicon is formed on the entire surface by epitaxial growth. By using epitaxial growth, the cap layer 95 is formed on the polycrystalline silicon film 90 so as to close the release opening 93. By forming the cap layer 95, the MEMS structures are sealed therein. Further, since the epitaxial growth is performed at a high temperature of about 600° C. to 1400° C., impurities such as organic substances adhering to the surface of the MEMS structure can be removed.

Step 19: As illustrated in FIG. 21, the surface of the cap layer 95 is planarized using CMP.

Step 20: As illustrated in FIG. 22, a metal film such as aluminum is formed on the cap layer 95 by vapor deposition, and then patterned to form electrode pads 30 and 33.

Step 21: By etching the cap layer 95 and the polycrystalline silicon film 90 around the electrode pads 30 and 33, the electrode pads 30 and 33 are electrically connected to the electrodes 80 and 83, respectively. Through the above steps, the MEMS resonator 100 illustrated in FIG. 2 is completed.

As described above, in the MEMS resonator according to the embodiment of the present invention, it is possible to provide the MEMS resonator with stable resonant vibration at low cost.

That is, in the producing step of the MEMS resonator according to the embodiment of the present invention, the MEMS structure is insulated from the substrate 10 using the isolation joint (IJ) 15. Therefore, it is not necessary to use an expensive substrate such as an SOI substrate, and the manufacturing cost can be reduced.

In addition, impurities such as organic substances adhering to the surface of the MEMS structure can be removed by the temperature (about 600 to 1400° C.) at the time of epitaxial growth of the cap layer 95, and a stable vibrator without degassing from the impurities or the like can be obtained.

The present disclosure provides a MEMS resonator that vibrates at a predetermined resonant frequency, the MEMS resonator including:
a substrate;
a cavity provided in the substrate;
a MEMS structure held within the cavity, the MEMS structure including:
   an anchor having a first end and a second end, the first end being connected to the substrate;
   a vibrator connected to the second end of the anchor and held in a hollow; and
   an electrode disposed around the vibrator, the vibrator and the electrode forming a capacitive vibrator; and
a cap layer which is formed over the substrate and seals the MEMS structure therein,
in which the anchor includes an isolation joint having an insulation property disposed to electrically insulate the first end from the second end.

By providing insulation using the isolation joint instead of an SOI substrate, the MEMS resonator can be provided at low cost.

In the present disclosure, the electrode and the substrate are also insulated by an isolation joint.

The manufacturing cost of the MEMS resonator can be reduced.

In the present disclosure, the cap layer is made of polycrystalline silicon.

Since the cap layer is produced at a relatively high temperature, impurities such as organic substances adhering to the surface of the MEMS structure can be removed, and a stable MEMS resonator without degassing from the impurities or the like can be obtained.

In the present disclosure, the anchor is a pair of anchors connected to both sides of the vibrator and extending on one axis, and the vibrator has a point-symmetrical shape with respect to a point on the one axis.

By using such a symmetrical structure, stable resonance can be obtained.

The present disclosure is a method for producing a MEMS resonator, comprising:
a step of preparing a substrate;
a MEMS structure producing step of etching the substrate to produce a lower cavity and a MEMS structure held in a hollow in the lower cab;
a step of depositing a sacrificial oxide film on the substrate;
a step of etching a part of the sacrificial oxide film to produce an upper cavity, and producing, from the lower cavity and the upper cavity, a cavity in which the MEMS structure is held; and
a sealing step of sealing the MEMS structure by depositing a cap layer made of polycrystalline silicon on the substrate.

Since the cap layer made of polycrystalline silicon is produced at a relatively high temperature instead of bonding the substrates by glass frit bonding, impurities such as organic substances adhering to the surface of the MEMS structure can be removed in this step, and a stable MEMS resonator without degassing from impurities or the like can be obtained.

In the present disclosure, the MEMS structure producing step includes a step of anisotropically etching the substrate to form a side surface of the MEMS structure, and a step of isotropically etching the substrate while the side surface is protected by an oxide film to form a bottom surface of the MEMS structure.

By using the structure etch and the structure release, the MEMS structure can be easily manufactured.

The present disclosure further includes, after forming a trench in the substrate, a step of filling an oxide having an insulation property in the trench, and the MEMS structure producing step includes, after the step of filling an oxide having an insulation property, a step of exposing a side surface and a bottom surface of the oxide to form an isolation joint that partially insulates the MEMS structure.

By using the isolation joint, the manufacturing cost can be reduced.

In the present disclosure, the sealing step is a step of forming a polycrystalline silicon film on the sacrificial oxide film and epitaxially growing the cap layer on the polycrystalline silicon film.

The cap layer can be epitaxially grown selectively from above the polycrystalline silicon film.

In the present disclosure, epitaxial growth is performed at a temperature of 800° C. or higher and 900° C. or lower.

By using such a temperature, impurities such as organic substances adhering to the surface of the MEMS structure can be removed, and a stable MEMS resonator without degassing from the impurities or the like can be obtained.

The MEMS resonator according to the present invention can be applied to an oscillation circuit and a filter using a resonant frequency, and a temperature sensor, a pressure sensor, a mass sensor, and the like using a shift of the resonant frequency.

What is claimed is:

1. A MEMS resonator that vibrates at a predetermined resonant frequency, the MEMS resonator comprising:
a substrate;
a cavity provided in the substrate;
a MEMS structure held within the cavity, the MEMS structure comprising:
an anchor having a first end and a second end, the first end being connected to the substrate;
a vibrator connected to the second end of the anchor and held in a hollow; and
an electrode disposed around the vibrator, the vibrator and the electrode forming a capacitive vibrator; and
a cap layer which is formed over the substrate and seals the MEMS structure therein,
wherein the anchor includes an isolation joint having an insulation property disposed to electrically insulate the first end from the second end.

2. The MEMS resonator according to claim 1, wherein the electrode and the substrate are also insulated by an isolation joint.

3. The MEMS resonator according to claim 1, wherein the cap layer is made of polycrystalline silicon.

4. The MEMS resonator according to claim 1, wherein the anchor is a pair of anchors connected to both sides of the vibrator and extending on one axis, and the vibrator has a point-symmetrical shape with respect to a point on the one axis.

5. A method for producing a MEMS resonator, comprising:
a step of preparing a substrate;
a MEMS structure producing step of etching the substrate to produce a lower cavity and a MEMS structure held in a hollow in the lower cab;
a step of depositing a sacrificial oxide film on the substrate;
a step of etching a part of the sacrificial oxide film to produce an upper cavity, and producing, from the lower cavity and the upper cavity, a cavity in which the MEMS structure is held; and
a sealing step of sealing the MEMS structure by depositing a cap layer made of polycrystalline silicon on the substrate.

6. The method according to claim 5, wherein the MEMS structure producing step comprises a step of anisotropically etching the substrate to form a side surface of the MEMS structure, and a step of isotropically etching the substrate while the side surface is protected by an oxide film to form a bottom surface of the MEMS structure.

7. The method according to claim 6, further comprising a step of filling an oxide having an insulation property in a trench after forming the trench in the substrate,
wherein the MEMS structure producing step comprises, after the step of filling an oxide having an insulation property, a step of exposing a side surface and a bottom surface of the oxide to form an isolation joint that partially insulates the MEMS structure.

8. The method according to claim 5, wherein the sealing step is a step of forming a polycrystalline silicon film on the sacrificial oxide film and epitaxially growing the cap layer on the polycrystalline silicon film.

9. The method according to claim 8, wherein the epitaxial growth is performed at a temperature of 800° C. or higher and 900° C. or lower.
